(19) United States
(12) Patent Application Publication
(10) Pub. No.: US 2023/0161925 A1
(43) Pub. Date: May 25, 2023

(54) PUNCHER DESIGN SYSTEM AND PUNCHER DESIGN METHOD

(71) Applicant: METAL INDUSTRIES RESEARCH & DEVELOPMENT CENTRE, KAOHSIUNG (TW)

(72) Inventors: Tang-Jyun WONG, Kaohsiung City (TW); Pin-Jyun CHEN, Kaohsiung City (TW)

(21) Appl. No.: 17/456,586

(22) Filed: Nov. 25, 2021

(51) Int. Cl. G06F 30/17; G06F 16/22; G06Q 30/06; G06N 5/02

(52) U.S. Cl. CPC G06F 30/17; G06F 16/2282; G06Q 30/0621; G06N 5/02

(57) ABSTRACT

A puncher design system and a puncher design method are provided. The puncher design system includes a data base module of parts, a knowledge base module, a graphic software module, a memory and a processor. The puncher design method includes: receiving plural sets of input parameter data; performing a puncher model generating step to use computer-aided design software to generate puncher part models according to the input parameter data, at least one of a standard parts library, a shared parts library and a customer demand specification table, and a database of puncher design knowledge, a database of material selection knowledge, a database of motor selection knowledge, and assemble the puncher part models to obtain a puncher model corresponding to a target puncher.

### BACKGROUND

### Field of Invention

The present invention relates to a puncher design system and a puncher design method.

### Description of Related Art

In the development of puncher industry, computer-aided design software is often used as a design assistant tool to reduce a cycle of designing and manufacturing of punchers. However, conventional design processes and parameter setting of the punchers are performed depending on the experience of the engineer, and the design process of the punchers is not parameterized or modularized. Therefore, the conventional design process of the punchers requires complex mathematical calculation and has a higher design threshold which are likely to cause human errors.

### SUMMARY

In order to solve the aforementioned problem, embodiments of the present invention provide a puncher design system and a puncher design method, which integrate professional design knowledges of punchers to automatically generate a puncher model required by the user based on parameter data input by the user, thereby avoiding complex mathematical calculation, shortening the development cycle of punchers, reducing human errors, lowering the design threshold of puncher design, and parameterizing experience accumulation of puncher design.

According to the aforementioned object, a puncher design system is provided. The puncher design system includes a part database module, a knowledge base module, a graphic software module, a memory and a processor. The part database module is configured to store at least one of a standard parts library, a shared parts library and a customer demand specification table. The standard parts library includes plural sets of standard parts data, the shared parts library includes plural sets of shared parts data, and the customer demand specification table includes plural sets of special specification parameter data. The knowledge base module is configured to store at least one of a database of puncher design knowledge, a database of material selection knowledge, a database of motor selection knowledge. The database of puncher design knowledge includes plural sets of puncher design knowledge data, the database of material selection knowledge includes plural sets of material selection knowledge data, and the database of motor selection knowledge includes plural sets of motor selection knowledge data. The graphic software module is configured to provide at least one computer-aided design software. The memory is configured to store a plurality of instructions. The processor is electrically connected to the memory to load the instructions to receive plural sets of input parameter data input from a user by using a user interface; and to perform a puncher model generating step by using the computer-aided design software to build a plurality of puncher part models and to assemble the puncher part models to obtain a puncher model corresponding to the target puncher. The input parameter data is corresponding to a target puncher required by the user. The puncher part models are built according to the input parameter data, and at least one of the standard parts library, the shared parts library and the customer demand specification table, and at least one of the database of puncher design knowledge, the database of material selection knowledge and the database of motor selection knowledge.

According to an embodiment of the present invention, when the puncher model generating step is performed by the processor, the processor further performs: selecting plural sets of target part data required to build the target puncher from at least of the standard parts library, the shared parts library and the customer demand specification table, and at least one of the database of puncher design knowledge, the database of material selection knowledge and the database of motor selection knowledge according to the input parameter data; selecting plural sets of target knowledge data required to build the target puncher from at least of the standard parts library, the shared parts library and the customer demand specification table according to the input parameter data; calculating a part shape of each of the puncher part models according to the target part data and the target knowledge data; generating the puncher part models by using the computer-aided design software according to the target part data, the target knowledge data and the part shape of each of the puncher part models; and assembling the puncher part models into the puncher model of the target puncher according to the target knowledge data.

According to an embodiment of the present invention, the puncher part models include a plurality of motor models, a plurality of connecting rod models and a plurality of sliding block models.

According to an embodiment of the present invention, when the processor is performed to build the puncher part models by using the at least one computer-aided design software according to the target part data and the target knowledge data, the processor further performs: using the at least one computer-aided design software to draw a plurality of part sketches and to stretch the part sketches, so as to obtain the puncher part models.

According to an embodiment of the present invention, the input parameter data includes punch tonnage, punch stroke, punch strokes per minute, tonnage rating point, base area of punching head, area of working platform and die height of the target puncher.

According to the aforementioned object, a puncher design method is provided. The puncher design method is performed by a puncher design system. The puncher design method includes: providing at least one of a standard parts library, a shared parts library and a customer demand specification table, in which the standard parts library includes plural sets of standard parts data, the shared parts library includes plural sets of shared parts data, and the customer demand specification table includes plural sets of special specification parameter data; providing at least one of a database of puncher design knowledge, a database of material selection knowledge, a database of motor selection knowledge, in which the database of puncher design knowledge includes plural sets of puncher design knowledge data, the database of material selection knowledge includes plural sets of material selection knowledge data, and the database of motor selection knowledge includes plural sets of motor selection knowledge data; receiving plural sets of input parameter data input from a user by using a user interface, in which the input parameter data is corresponding to a target puncher required by the user; performing a puncher model generating step by using a computer-aided design software to generate a plurality of puncher part models and to assemble the puncher part models to obtain a puncher model corresponding to the target puncher, in which the puncher part models are generated according to the input parameter data, and at least one of the standard parts library, the shared parts library and the customer demand specification table, and at least one of the database of puncher design knowledge, the database of material selection knowledge and the database of motor selection knowledge.

According to an embodiment of the present invention, the puncher model generating step includes: selecting plural sets of target part data required to construct the target puncher from at least of the standard parts library, the shared parts library and the customer demand specification table, and at least one of the database of puncher design knowledge, the database of material selection knowledge and the database of motor selection knowledge according to the input parameter data; selecting plural sets of target knowledge data required to construct the target puncher from at least of the standard parts library, the shared parts library and the customer demand specification table according to the input parameter data; calculating a part shape of each of the puncher part models according to the target part data and the target knowledge data; generating the puncher part models by using the computer-aided design software according to the target part data, the target knowledge data and the part shape of each of the puncher part models; and assembling the puncher part models into the puncher model of the target puncher according to the target knowledge data.

According to an embodiment of the present invention, the puncher part models include a plurality of motor models, a plurality of connecting rod models and a plurality of sliding block models.

According to an embodiment of the present invention, when the puncher part models are generated by using the at least one computer-aided design software according to the target part data and the target knowledge data, the at least one computer-aided design software is further used to draw a plurality of part sketches and to stretch the part sketches, so as to obtain the puncher part models.

According to an embodiment of the present invention, the input parameter data includes punch tonnage, punch stroke, punch strokes per minute, tonnage rating point, base area of punching head, area of working platform and die height of the target puncher.

According to the aforementioned object, another puncher design system is provided. The puncher design system includes a user interface module, a part database module, a knowledge base module, a graphic software module and an inference engine module. The user interface module is configured to provide a user interface to receive a plurality set of input parameter data input by a user, in which the input parameter data is corresponding to a target puncher required by the user. The part database module is configured to store at least one of a standard parts library, a shared parts library and a customer demand specification table, in which the standard parts library includes plural sets of standard parts data, the shared parts library includes plural sets of shared parts data, and the customer demand specification table includes plural sets of special specification parameter data. The knowledge base module is configured to store at least one of a database of puncher design knowledge, a database of material selection knowledge, a database of motor selection knowledge, in which the database of puncher design knowledge includes plural sets of puncher design knowledge data, the database of material selection knowledge includes plural sets of material selection knowledge data, and the database of motor selection knowledge includes plural sets of motor selection knowledge data. The graphic software module is configured to provide at least one computer-aided design software. The inference engine module is electrically connected to the user interface module, the part database module, the knowledge base module and the graphic software module. The inference engine module is configured to receive the input parameter data to build a plurality of puncher part models by using the at least one computer-aided design software and is configured to assemble the puncher part models into a puncher model corresponding to the target puncher. The puncher part models are built according to the input parameter data, and at least one of the standard parts library, the shared parts library and the customer demand specification table, and at least one of the database of puncher design knowledge, the database of material selection knowledge and the database of motor selection knowledge.

According to an embodiment of the present invention, the inference engine module includes an inference submodule, a parts selecting submodule, a shape parameter calculating submodule, a solid model generating submodule and a solid model assembling submodule. The inference submodule is electrically connected to the user interface module, and the inference submodule is configured to receive the input parameter data. The parts selecting submodule is electrically connected to the inference submodule, the part database module and the knowledge base module. The inference submodule uses the parts selecting submodule to select plural sets of target part data required to construct the target puncher from at least of the standard parts library, the shared parts library and the customer demand specification table, and at least one of the database of puncher design knowledge, the database of material selection knowledge and the database of motor selection knowledge according to the input parameter data. The shape parameter calculating submodule electrically is connected to the inference submodule and the knowledge base module. The inference submodule uses the shape parameter calculating submodule to select plural sets of target knowledge data required to construct the target puncher from at least of the standard parts library, the shared parts library and the customer demand specification table according to the input parameter data. The shape parameter calculating submodule further calculates a part shape of each of the puncher part models according to the target part data and the target knowledge data. The solid model generating submodule is electrically connected to the inference submodule. The inference submodule uses the solid model generating submodule to generate the puncher part models by using the at least one computer-aided design software according to the target part data, the target knowledge data and the part shape of each of the puncher part models. The solid model assembling submodule is electrically connected to the inference submodule. The inference submodule uses the solid model assembling submodule to assemble the puncher part models into the puncher model of the target puncher according to the target knowledge data.

According to an embodiment of the present invention, the puncher part models include a plurality of motor models, a plurality of connecting rod models and a plurality of sliding block models.

According to an embodiment of the present invention, the inference submodule uses the solid model generating submodule to generate the puncher part models by using the at least one computer-aided design software according to the target part data, the target knowledge data and the part shape of each of the puncher part models, the inference submodule further controls the solid model generating submodule so as to obtain the puncher part models.

According to an embodiment of the present invention, the input parameter data includes punch tonnage, punch stroke, punch strokes per minute, tonnage rating point, base area of punching head, area of working platform and die height of the target puncher.

### BRIEF DESCRIPTION OF THE DRAWINGS

The invention can be more fully understood by reading the following detailed description of the embodiment, with reference made to the accompanying drawings as follows:

FIG. 1 is a schematic diagram showing a functional block diagram of a puncher design system in accordance with an embodiment of the present invention;

FIG. 2 is a schematic diagram showing a user interface in accordance with an embodiment of the present invention;

FIG. 3 is a schematic diagram showing a design knowledge related to a connecting rod;

FIG. 4 is a schematic flowchart of a puncher design method in accordance with an embodiment of the present invention;

FIG. 5 is a schematic flowchart of the step of generating a puncher model in accordance with an embodiment of the present invention; and

FIG. 6A and FIG. 6B are schematic diagrams showing a stretch process of a puncher part model in accordance with an embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

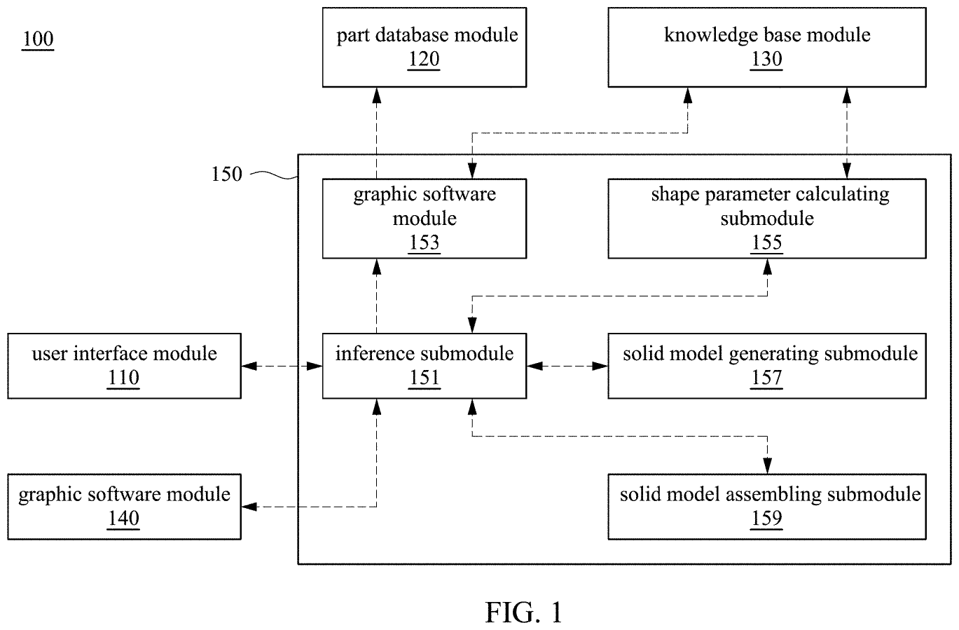

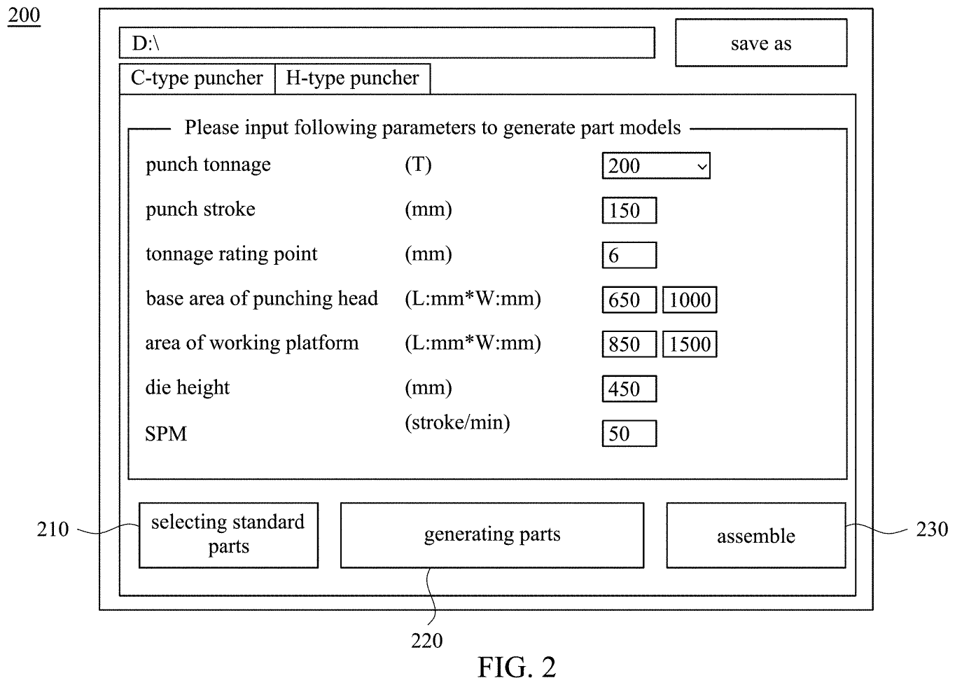

Referring to FIG. 1, FIG. 1 is a schematic diagram showing a functional block diagram of a puncher design system 100 in accordance with an embodiment of the present invention. The puncher design system 100 includes a user interface module 110, a part database module 120, a knowledge base module 130, a graphic software module 140 and an inference engine module 150. The user interface module 110 is configured to provide a user interface 200. As shown in FIG. 2, the user interface 200 is configured to provide a user to input plural sets of input parameter data. The input parameter data is corresponding to a target puncher required by the user. In some embodiments, the input parameter data includes punch tonnage, punch stroke, punch strokes per minute (SPM), tonnage rating point, base area of punching head, area of working platform and die height of the target puncher, but the embodiments of the present invention are not limited thereto. The user interface 200 of an embodiment of the present invention further includes several function buttons 210-230 for the user to select required operations. In other embodiments of the present invention, after the user input the input parameter data of the target puncher, the puncher design system 100 can automatically generate a puncher model corresponding to the target puncher.

The part database module120 is configured to store at least one of a standard parts library, a shared parts library and a customer demand specification table. The standard parts library includes plural sets of standard parts data, such as data of parts sold on the market. The shared parts library includes plural sets of shared parts data, such as parts specifications data which is not disclosed by the company. The customer demand specification table includes plural sets of parts data with special customer-required specification. The part database module 120 of an embodiment of the present invention stores a standard parts library, a shared parts library and a customer demand specification table at the same time, but the embodiments of the present invention are not limited thereto. The data stored in the part database module 120 can be determined according to user requirements. For example, in some embodiments, the part database module 120 can only store the standard parts library.

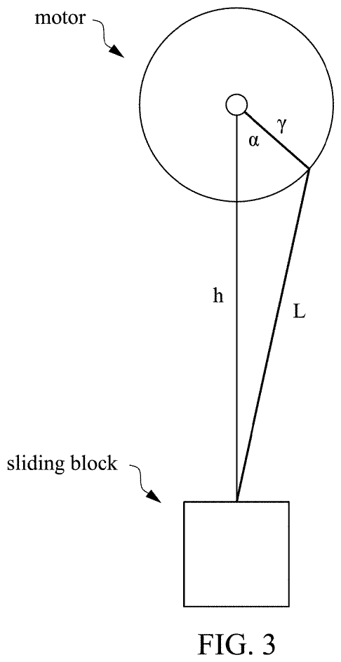

The knowledge base module 130 is configured to store at least one of a database of puncher design knowledge, a database of material selection knowledge and a database of motor selection knowledge. The database of puncher design knowledge includes various information related to parts design knowledge. Taking a design knowledge of a connecting rod as an example, as shown in FIG. 3, the design knowledge of the connecting rod can be expressed as the following equations (1)-(4):

F=M/(r*sin α)=2M/(s*sin α) (1);

M=(F*s*sin α)/2 (2);

d=r*(1−cos α) (3);

h=r*cos α+(r2*(cos 2α−1)+L2)1/2 (4);

where “F” represents a nominal capacity; “α” represents a nominal angle; “s” represents a stroke; “M” represents a required torque; “h” is a location of a piston pin (which is calculated from a center of a crankshaft); “L” is a length of the connecting rod; and “r” is a crank radius.

The database of material selection knowledge includes plural sets of material selection knowledge data of various parts, such as a material selection knowledge data of the connecting rod. The database of motor selection knowledge includes plural sets of motor selection knowledge data, such as relationship between the punch tonnage and the motor.

The graphic software module is configured to store at least one computer-aided design software. In the present embodiment, the graphic software module 140 is configured to store and to provide “Solid Edge” and “Inventor”, but the embodiments of the present invention are not limited thereto. In other embodiments of the present invention, the graphic software module 140 is configured to store and to provide “SolidWorks”.

The inference engine module 150 is electrically connected to the user interface module 110, the part database module 120, the knowledge base module 130 and the graphic software module 140 to receive the input parameter data. The inference engine module 150 further generates a plurality of puncher part models according to the input parameter data, the standard parts library, the shared parts library and the customer demand specification table, the database of puncher design knowledge, the database of material selection knowledge and the database of motor selection knowledge by using the computer-aided design software, and inference engine module 150 further then assembles the puncher part models into a puncher model corresponding to the target puncher. The puncher part models and the assembled puncher model are presented by the computer-aided design software.

The puncher design system 100 of the embodiment of the present invention can be implemented by a computer device. More specifically, the computer device includes a memory, a processor and a hard disk. The memory is configured to store plural instructions, and the processor is configured to load the instructions so as to achieve the functions of the user interface module 110, the part database module 120, the knowledge base module 130, the graphic software module 140 and the inference engine module 150. In the present embodiment, data related to the part database module 120, the knowledge base module 130 and the graphic software module 140 are stored in the hard disk, but the embodiments of the present invention are not limited thereto.

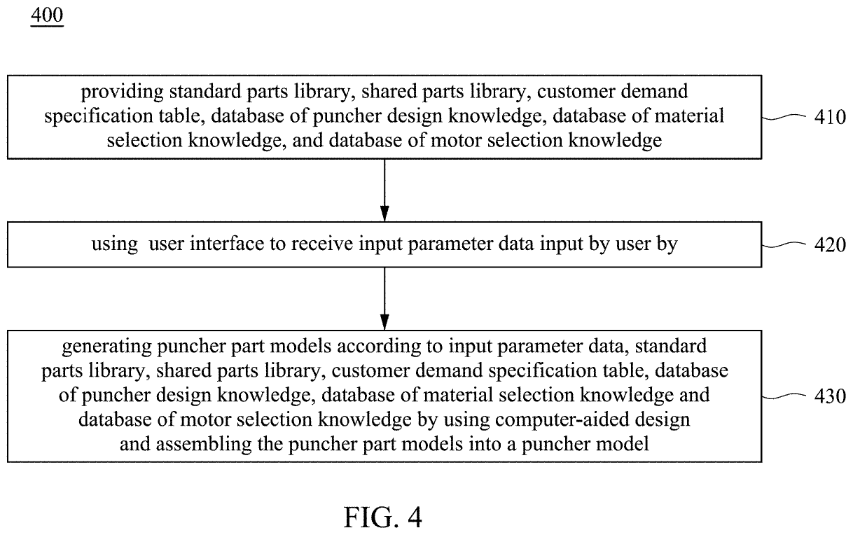

Referring to FIG. 4, FIG. 4 is a schematic flowchart of a puncher design method 400 in accordance with an embodiment of the present invention. The puncher design method 400 is executed by the puncher design system 100, so as to generate the puncher part models and a finish-assembled puncher model.

In the puncher design method 400, a step 410 is first performed to provide the standard parts library, the shared parts library, the customer demand specification table, the database of puncher design knowledge, the database of material selection knowledge, the database of motor selection knowledge and the computer-aided design software by using the part database module 120, the knowledge base module 130 and the graphic software module 140. Then, a step 420 is performed to use the user interface 200 to receive the input parameter data input by the user. Thereafter, a step 430 is performed to generate a puncher model. The step 430 of generating the puncher model is performed according to the input parameter data, the standard parts library, the shared parts library, the customer demand specification table, the database of puncher design knowledge, the database of material selection knowledge and the database of motor selection knowledge by using the computer-aided design software to generate plural puncher part models and to assemble the puncher part models into a puncher model which is corresponding to the target puncher.

The following will explain how an inference submodule 151 of the inference engine module 150 uses other submodules to generate the assembled puncher model.

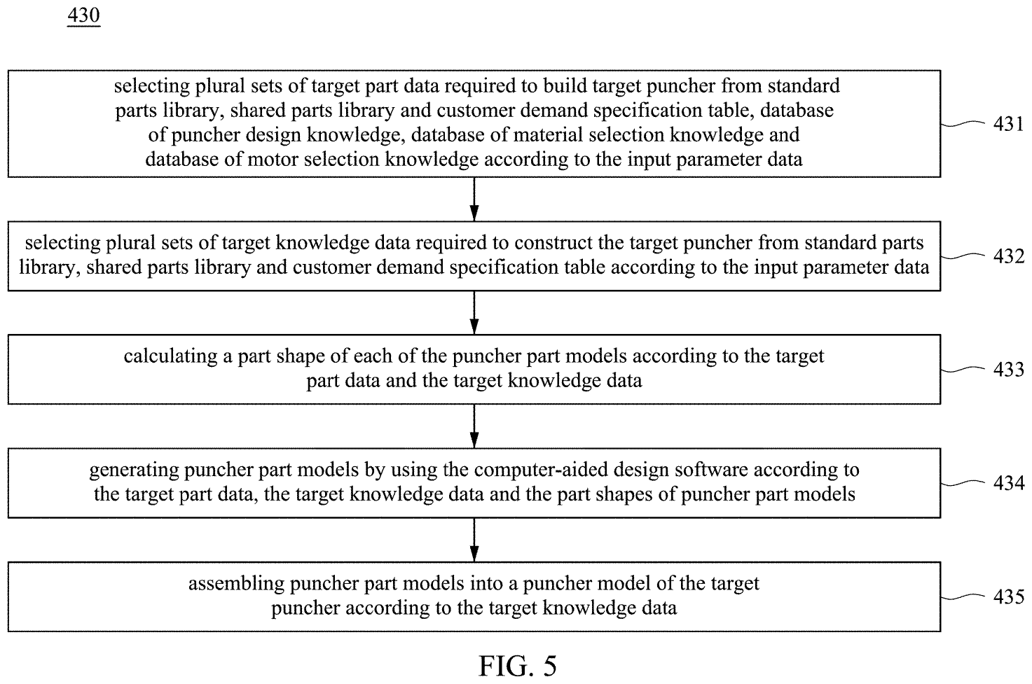

Referring to FIG. 5, FIG. 5 is a schematic flowchart of the step 430 of generating the puncher model in accordance with an embodiment of the present invention. In the step 430, a step 431 is first performed to select plural sets of target part data required to construct the target puncher from the standard parts library, the shared parts library and the customer demand specification table, the database of puncher design knowledge, the database of material selection knowledge and the database of motor selection knowledge according to the input parameter data. More specifically, in the step 431, the inference submodule 151 of the inference engine module 150 uses a parts selecting submodule 153 to select the target part data from the standard parts library, the shared parts library and the customer demand specification table, the database of puncher design knowledge, the database of material selection knowledge and the database of motor selection knowledge according to the input parameter data. For example, the parts selecting submodule 153 is used to select a data of a required connecting rod, to select a data of a required motor, or to select a data of a required sliding block.

Thereafter, a step 432 is performed to select plural sets of target knowledge data required to construct the target puncher from the standard parts library, the shared parts library and the customer demand specification table according to the input parameter data. The target knowledge data includes, for example, configurations, size and assembly method of required parts. More specifically, in the step 432, the inference submodule 151 of the inference engine module 150 uses the shape parameter calculating submodule 155 to select plural sets of target knowledge data from the standard parts library, the shared parts library and the customer demand specification table according to the input parameter data.

Then, a step 433 is performed to calculate a part shape of each of the puncher part models according to the target part data and the target knowledge data. More specifically, in the step 433, the inference submodule 151 of the inference engine module 150 uses the shape parameter calculating submodule 155 to calculate the part shapes of the puncher part models according to the target part data and the target knowledge data. For example, the shape parameter calculating submodule 155 is used to calculate part shapes of the puncher part models according to the target part data. For example, the shape parameter calculating submodule 155 is used to calculate a shape of a required connecting rod, to calculate a shape of a required motor, or to calculate a shape of a required sliding block.

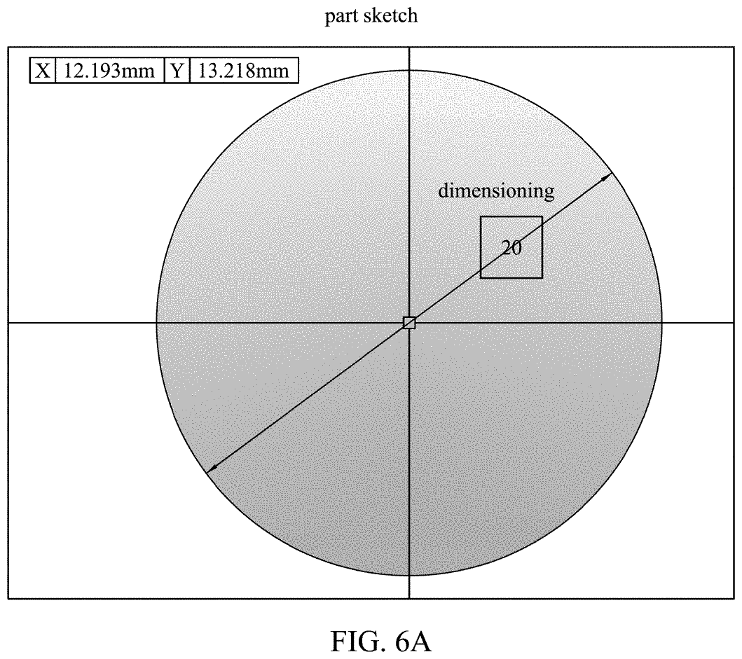

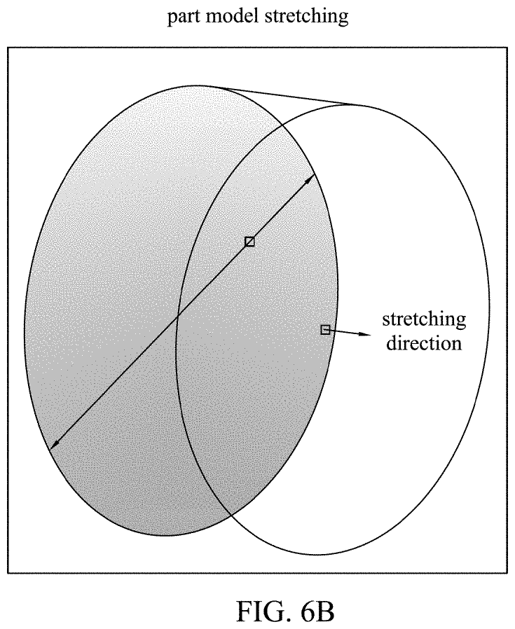

Thereafter, a step 434 is performed to generate the puncher part models by using the computer-aided design software according to the target part data, the target knowledge data and the part shapes of the puncher part models. More specifically, the inference submodule 151 of the inference engine module 150 controls a solid model generating submodule 157 to use the computer-aided design software to draw plural part sketches and stretch the part sketches, so as to obtain the puncher part models. For example, the solid model generating submodule 157 is used to generate a model of a required connecting rod, to generate a model of a required motor, or to generate a model of a required sliding block. More specifically, as shown in FIG. 6A and FIG. 6B, a sketch of an end portion of a connecting rod is first drawn, and the sketch is stretched to form a model of the connecting rod.

Then, a step 435 is performed to generate the puncher model of the target puncher according to the target knowledge data according to the target knowledge data. More specifically, in the step 435, the inference submodule 151 of the inference engine module 150 controls a solid model assembling submodule 159 to assemble the puncher part models into the puncher model of the target puncher according to the target knowledge data. For example, the solid model assembling submodule 159 assemble the motor model, the connecting rod model and the sliding block model together according to the target knowledge data.

It is to be understood that, the embodiments of the puncher design system 100 and the puncher design method 400 of the present invention integrate professional design knowledges of punchers to automatically generate a puncher model required by the user based on parameter data input by the user, thereby avoiding complex mathematical calculation, shortening the development cycle of punchers, reducing human errors, lowering the design threshold of puncher design, and parameterizing experience accumulation of puncher design.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A puncher design system, comprising:
a part database module configured to store at least one of a standard parts library, a shared parts library and a customer demand specification table, wherein the standard parts library comprises a plurality sets of standard parts data, the shared parts library comprises a plurality sets of shared parts data, and the customer demand specification table comprises a plurality sets of special specification parameter data;
a knowledge base module configured to store at least one of a database of puncher design knowledge, a database of material selection knowledge, a database of motor selection knowledge, wherein the database of puncher design knowledge comprises a plurality sets of puncher design knowledge data, the database of material selection knowledge comprises a plurality sets of material selection knowledge data, and the database of motor selection knowledge comprises a plurality sets of motor selection knowledge data;
a graphic software module configured to provide at least one computer-aided design software;
a memory configured to store a plurality of instructions;
a processor electrically connected to the memory to load the instructions to:
receive a plurality sets of input parameter data input from a user by using a user interface, wherein the input parameter data is corresponding to a target puncher required by the user;
perform a puncher model generating step by using the computer-aided design software to build a plurality of puncher part models and to assemble the puncher part models to obtain a puncher model corresponding to the target puncher, wherein the puncher part models are built according to the input parameter data, and at least one of the standard parts library, the shared parts library and the customer demand specification table, and at least one of the database of puncher design knowledge, the database of material selection knowledge and the database of motor selection knowledge.

2. The puncher design system of claim 1, wherein when the puncher model generating step is performed by the processor, the processor further performs:
selecting a plurality sets of target part data required to build the target puncher from at least of the standard parts library, the shared parts library and the customer demand specification table, and at least one of the database of puncher design knowledge, the database of material selection knowledge and the database of motor selection knowledge according to the input parameter data;
selecting a plurality sets of target knowledge data required to build the target puncher from at least of the standard parts library, the shared parts library and the customer demand specification table according to the input parameter data;
calculating a part shape of each of the puncher part models according to the target part data and the target knowledge data;
generating the puncher part models by using the computer-aided design software according to the target part data, the target knowledge data and the part shape of each of the puncher part models; and
assembling the puncher part models into the puncher model of the target puncher according to the target knowledge data.

3. The puncher design system of claim 1, wherein the puncher part models comprise a plurality of motor models, a plurality of connecting rod models and a plurality of sliding block models.

4. The puncher design system of claim 1, wherein when the processor is performed to build the puncher part models by using the at least one computer-aided design software according to the target part data and the target knowledge data, the processor further performs:
using the at least one computer-aided design software to draw a plurality of part sketches and to stretch the part sketches, so as to obtain the puncher part models.

5. The puncher design system of claim 1, wherein the input parameter data comprises punch tonnage, punch stroke, punch strokes per minute, tonnage rating point, base area of punching head, area of working platform and die height of the target puncher.

6. A puncher design method, which is performed by a puncher design system, wherein the puncher design method comprises:
providing at least one of a standard parts library, a shared parts library and a customer demand specification table, wherein the standard parts library comprises a plurality sets of standard parts data, the shared parts library comprises a plurality sets of shared parts data, and the customer demand specification table comprises a plurality sets of special specification parameter data;
providing at least one of a database of puncher design knowledge, a database of material selection knowledge, a database of motor selection knowledge, wherein the database of puncher design knowledge comprises a plurality sets of puncher design knowledge data, the database of material selection knowledge comprises a plurality sets of material selection knowledge data, and the database of motor selection knowledge comprises a plurality sets of motor selection knowledge data;
receiving a plurality sets of input parameter data input from a user by using a user interface, wherein the input parameter data is corresponding to a target puncher required by the user;
performing a puncher model generating step by using a computer-aided design software to build a plurality of puncher part models and to assemble the puncher part models to obtain a puncher model corresponding to the target puncher, wherein the puncher part models are built according to the input parameter data, and at least one of the standard parts library, the shared parts library and the customer demand specification table, and at least one of the database of puncher design knowledge, the database of material selection knowledge and the database of motor selection knowledge.

7. The puncher design method of claim 6, wherein the puncher model generating step comprises:
selecting a plurality sets of target part data required to build the target puncher from at least of the standard parts library, the shared parts library and the customer demand specification table, and at least one of the database of puncher design knowledge, the database of material selection knowledge and the database of motor selection knowledge according to the input parameter data;
selecting a plurality sets of target knowledge data required to build the target puncher from at least of the standard parts library, the shared parts library and the customer demand specification table according to the input parameter data;
calculating a part shape of each of the puncher part models according to the target part data and the target knowledge data;
generating the puncher part models by using the computer-aided design software according to the target part data, the target knowledge data and the part shape of each of the puncher part models; and
assembling the puncher model of the target puncher according to the target knowledge data.

8. The puncher design method of claim 6, wherein the puncher part models comprise a plurality of motor models, a plurality of connecting rod models and a plurality of sliding block models.

9. The puncher design method of claim 6, wherein when the puncher part models are built by using the at least one computer-aided design software according to the target part data and the target knowledge data, the at least one computer-aided design software is further used to draw a plurality of part sketches and to stretch the part sketches, so as to obtain the puncher part models.

10. The puncher design method of claim 6, wherein the input parameter data comprises punch tonnage, punch stroke, punch strokes per minute, tonnage rating point, base area of punching head, area of working platform and die height of the target puncher.

11. A puncher design system, comprising:
a user interface module configured to provide a user interface to receive a plurality set of input parameter data input by a user, wherein the input parameter data is corresponding to a target puncher required by the user;
a part database module configured to store at least one of a standard parts library, a shared parts library and a customer demand specification table, wherein the standard parts library comprises a plurality sets of standard parts data, the shared parts library comprises a plurality sets of shared parts data, and the customer demand specification table comprises a plurality sets of special specification parameter data;
a knowledge base module configured to store at least one of a database of puncher design knowledge, a database of material selection knowledge, a database of motor selection knowledge, wherein the database of puncher design knowledge comprises a plurality sets of puncher design knowledge data, the database of material selection knowledge comprises a plurality sets of material selection knowledge data, and the database of motor selection knowledge comprises a plurality sets of motor selection knowledge data;
a graphic software module configured to provide at least one computer-aided design software;
an inference engine module electrically connected to the user interface module, the part database module, the knowledge base module and the graphic software module, wherein the inference engine module is configured to receive the input parameter data to build a plurality of puncher part models by using the at least one computer-aided design software and is configured to assemble the puncher part models to obtain a puncher model corresponding to the target puncher, wherein the puncher part models are built according to the input parameter data, and at least one of the standard parts library, the shared parts library and the customer demand specification table, and at least one of the database of puncher design knowledge, the database of material selection knowledge and the database of motor selection knowledge.

12. The puncher design system of claim 11, wherein the inference engine module comprises:
an inference submodule electrically connected to the user interface module, wherein the inference submodule is configured to receive the input parameter data;
a parts selecting submodule electrically connected to the inference submodule, the part database module and the knowledge base module, wherein the inference submodule uses the parts selecting submodule to select a plurality sets of target part data required to build the target puncher from at least of the standard parts library, the shared parts library and the customer demand specification table, and at least one of the database of puncher design knowledge, the database of material selection knowledge and the database of motor selection knowledge according to the input parameter data;
a shape parameter calculating submodule electrically connected to the inference submodule and the knowledge base module, wherein the inference submodule uses the shape parameter calculating submodule to select a plurality sets of target knowledge data required to build the target puncher from at least of the standard parts library, the shared parts library and the customer demand specification table according to the input parameter data, and the shape parameter calculating submodule further calculates a part shape of each of the puncher part models according to the target part data and the target knowledge data;
a solid model generating submodule electrically connected to the inference submodule, wherein the inference submodule uses the solid model generating submodule to generate the puncher part models by using the at least one computer-aided design software according to the target part data, the target knowledge data and the part shape of each of the puncher part models; and
a solid model assembling submodule electrically connected to the inference submodule, wherein the inference submodule uses the solid model assembling submodule to assemble the puncher model of the target puncher according to the target knowledge data.

13. The puncher design system of claim 12, wherein the puncher part models comprise a plurality of motor models, a plurality of connecting rod models and a plurality of sliding block models.

14. The puncher design system of claim 12, wherein when the inference submodule uses the solid model generating submodule to generate the puncher part models by using the at least one computer-aided design software according to the target part data, the target knowledge data and the part shape of each of the puncher part models, the inference submodule further controls the solid model generating submodule so as to obtain the puncher part models.

15. The puncher design system of claim 11, wherein the input parameter data comprises punch tonnage, punch stroke, punch strokes per minute, tonnage rating point, base area of punching head, area of working platform and die height of the target puncher.
